(19) United States
(12) Patent Application Publication
(10) Pub. No.: US 2013/0000970 A1
(43) Pub. Date: Jan. 3, 2013

(54) ELECTROMAGNETIC SHIELD

(75) Inventor: TEN-CHEN HO, Tu-Cheng (TW)

(73) Assignee: HON HAI PRECISION INDUSTRY CO., LTD., Tu-Cheng (TW)

(21) Appl. No.: 13/315,680

(22) Filed: Dec. 9, 2011

(30) Foreign Application Priority Data
Jun. 29, 2011 (CN) 201110178322.1

(51) Int. Cl. H05K 9/00

(52) U.S. Cl. 174/388; 174/350

(57) ABSTRACT

An electromagnetic shield includes a base layer, a wire mesh, and two ground wires. The wire mesh is embedded in the base layer, and includes a number of first wires and a number of second wires intersecting with the first wires to form a number of cells. The first and second wires are made of conductive material. The ground wires are respectively arranged on two opposite sides of the wire mesh and connected to the first and second wires.

### BACKGROUND

1. Technical Field

The present disclosure relates to an electromagnetic shield.

2. Description of Related Art

At present, electromagnetic shield comprises glass embedded wire mesh. However, such material is difficult to bend, cut, or otherwise shape into a desired configuration. Therefore, there is room for improvement in the art.

### BRIEF DESCRIPTION OF THE DRAWINGS

Many aspects of the embodiments can be better understood with parameter to the following drawings. The components in the drawings are not necessarily drawn to scale, the emphasis instead being placed upon clearly illustrating the principles of the present embodiments. Moreover, in the drawings, like parameter numerals designate corresponding parts throughout the several views.

FIG. 1 is a cross-sectional view of an electromagnetic shield in accordance with an exemplary embodiment of the present disclosure.

FIG. 2 is a schematic view of the electromagnetic shield of FIG. 1.

### DETAILED DESCRIPTION

The disclosure, including the drawing, is illustrated by way of example and not by way of limitation. Parameters to “an” or “one” embodiment in this disclosure are not necessarily to the same embodiment, and such parameters mean at least one.

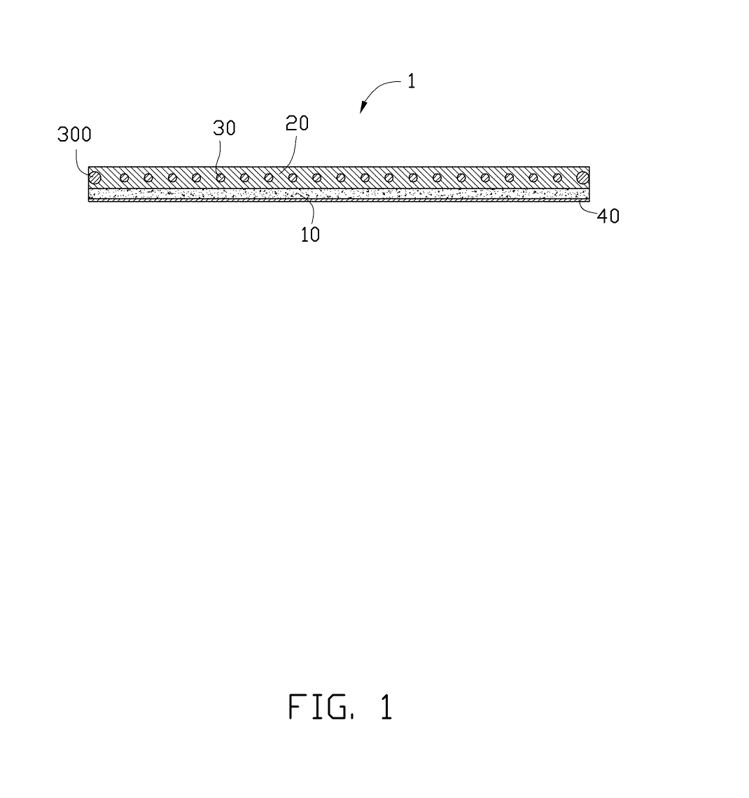

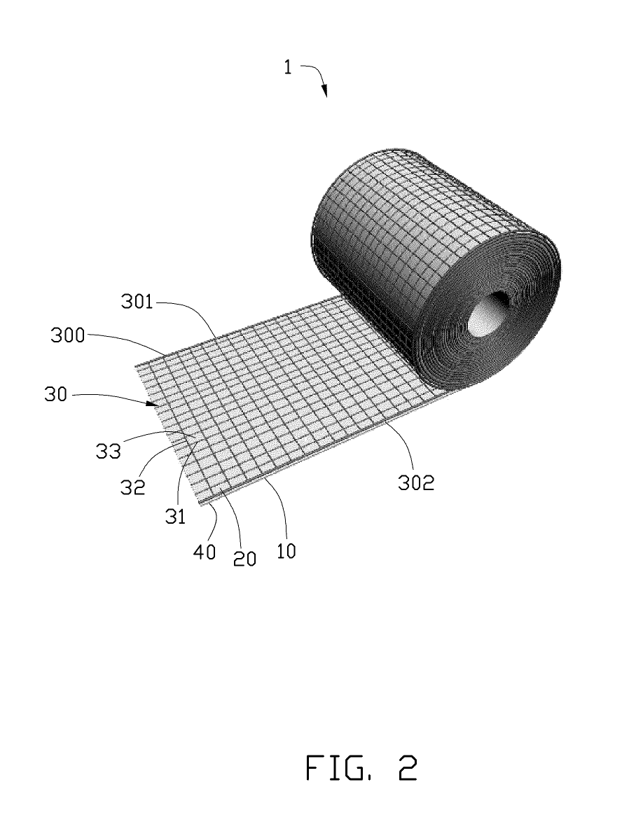

Referring to FIGS. 1 and 2, an electromagnetic shield 1 in accordance with an exemplary embodiment includes a base layer 20, an adhesive layer 10 attached to a side of the base layer 20, a covering layer 40 attached to a side of the adhesive layer 10. The covering layer 40 and the base layer 20 sandwiches the adhesive layer 10. A wire mesh 30 is embedded in the base layer 20 by melting the base layer 20 around and on the wire mesh 30. The base layer 20 is made of material that is flexible, such as polyethylene, polyester, nylon, or polyvinyl. The wire mesh 30 includes a plurality of parallel wires 31 and a plurality of parallel wires 32 perpendicularly intersecting the wires 31, to form a plurality of cells 33. The wires 31 and 32 are made of conductive material, such as gold, silver, copper, or aluminum. Ground wires 300 are arranged on two opposite sides 301 and 302 of the wire mesh 30 and connected to the corresponding wires 31 and 32. Diameters of the ground wires 300 are greater than diameters of the wires 31 and 32. The shield 1 can be adhered to an object, which needs to be shielded, by the adhesive layer 10 after the covering layer 40 is peeled off. The shield 1 can be roll packed, thus use, storage, and transport are convenient. In other embodiments the cell 33 may instead be a mesh and the wires 31, 32 cross each other in other than perpendicular angles forming spaces that may be diamond-shaped or other similar shapes.

A distance between two adjacent wires 31 or a distance between two adjacent wires 32 is less than or equal to a half of the electromagnetic wave length radiated by the shielded object. For example, the electromagnetic shield 1 is adhered to an object, to shield electromagnetic waves whose frequency is less than 30 gigahertz (GHz). In design, the diameters of the wires 31 and 32 are less than or equal to 0.1 millimeters, and the distance between two adjacent wires 31 or the distance between two adjacent wires 32 is less than or equal to 5 millimeters. The diameters of the ground wires 300 are 1 millimeter.

In use, the electromagnetic shield 1 is adhered to an object, which needs to be shielded, through the adhesive layer 10 after the covering layer 40 is peeled off. The ground wires 300 can be grounded through a ground wire of the shielded object. Due to the distance between two adjacent wires 31 or the distance between two adjacent wires 32 being less than or equal to a half of an electromagnetic wave length radiated by the shielded object, and the wire mesh 30 being grounded through the ground wires 300, the electromagnetic shield 1 has a good electromagnetic shielding function.

Even though numerous characteristics and advantages of the disclosure have been set forth in the foregoing description, together with details of the structure and function of the disclosure, the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. An electromagnetic shield comprising:
a base layer;
a wire mesh embedded in the base layer, and comprising a plurality of first wires and a plurality of second wires intersecting with the first wires to form a plurality of cells, wherein the first and second wires are made of conductive material; and
two ground wires arranged on two opposite sides of the wire mesh and connected to the corresponding first and second wires.

2. The electromagnetic shield of claim 1, wherein the first wires are parallel to one another, and the second wires are parallel to one another and perpendicular to the first wires.

3. The electromagnetic shield of claim 1, wherein a distance between any two adjacent first wires or any two adjacent second wires is less than or equal to a half of an electromagnetic wave length to be shielded.

4. The electromagnetic shield of claim 1, wherein the first and second wires are made of gold, silver, copper, or aluminum.

5. The electromagnetic shield of claim 1, wherein diameters of the first and second wires are less than or equal to 0.1 millimeters.

6. The electromagnetic shield of claim 1, wherein diameters of the ground wires are greater than diameters of the first and second wires.

7. The electromagnetic shield of claim 1, wherein the base layer is made of polyethylene, polyester, nylon, or polyvinyl.

8. The electromagnetic shield of claim 1, wherein a shape of each cell is rectangular.

9. The electromagnetic shield of claim 1, further comprising an adhesive layer attached to a side of the base layer and a covering layer attached to a side of the adhesive layer and sandwich the adhesive layer with the base layer.
